(19) United States
(12) Patent Application Publication
(10) Pub. No.: US 2024/0166947 A1
(43) Pub. Date: May 23, 2024

(54) SUBSTRATE TREATING SOLUTION, AND USING THE SAME, METHOD FOR MANUFACTURING SUBSTRATE AND METHOD FOR MANUFACTURING DEVICE

(71) Applicant: MERCK PATENT GMBH, Darmstadt (DE)

(72) Inventors: Takashi SEKITO, Kakegawa-shi (JP); Tatsuro NAGAHARA, Kakegawa-shi (JP)

(21) Appl. No.: 18/282,300

(22) PCT Filed: Mar. 17, 2022
(86) PCT No.: PCT/EP2022/056905

§ 371 Date: Sep. 15, 2023

(30) Foreign Application Priority Data
Mar. 19, 2021 (JP) 2021-045729

(51) Int. Cl. C09K 13/00

(52) U.S. Cl. CPC C09K 13/00

(57) ABSTRACT

[Problem] To provide a substrate treating solution. [Means for Solution] The substrate treating solution comprises a polymer (A) and a solvent (B), wherein the solvent (B) comprises water (B-1); the polymer (A) comprises an acidic polymer (A-1) having a pKa (H₂O) of −10 to 8 or a basic polymer (A-2) whose conjugate acid has a pKa (H₂O) of 6 to 14; the content of the polymer (A) is 0.5 to 15 mass % based on the total mass of the substrate treating solution; the content of the solvent (B) is 70 to 99.5 mass % based on the total mass of the substrate treating solution; and the content of water (B-1) is 80 to 100 mass % based on the total mass of the solvent (B).

### BACKGROUND OF THE INVENTION

### Technical Field

The present invention relates to a substrate treating solution and a method for treating a substrate using the same.

### Background Art

In the process of manufacturing semiconductor devices and the like, debris may attach on a substrate, and a cleaning step may be performed to remove debris. In the cleaning step, there are methods such as a method for physically removing particles by supplying a cleaning solution such as deionized water (DIW: Deionized water) on the substrate and a method for chemically removing particles with chemicals.

When metal attaches as debris, it may be difficult to remove debris only by applying deionized water. For example, a method for removing debris using a mixed liquid of hydrogen peroxide solution and hydrochloric acid, a method for removing by supplying chemicals containing an ionic surfactant (Patent Document 1), and a method including a step of charging a substrate and a step of immersing the substrate in chemicals (Patent Document 2) have been proposed.

A method for etching a metal oxide layer with a liquid such as dilute hydrofluoric acid (Patent Document 3) has been studied.

### PRIOR ART DOCUMENTS

### Patent Documents

[Patent Document 1] US 2020/0328075 A1

[Patent Document 2] JP 2020-72190 A

[Patent Document 3] JP 2020-155615 A

### SUMMARY OF THE INVENTION

### Problems to be Solved by the Invention

The present inventors considered that there are still one or more problems still need improvements with respect to the technology for removing debris being on the substrate. Examples of these include the following: removal of debris is not efficient; debris containing metal cannot be completely removed and remains on the substrate; reattachment of debris occurs; the components of the substrate treating solution remain on the substrate surface; the substrate surface cannot be cleaned without using a highly reactive liquid; the liquid to be used is at high risk; the substrate treating solution chemically damages the substrate surface; additional treatment, such as the substrate is intentionally charged, is required; the substrate surface cannot be etched as intended; the etched substrate surface becomes rough.

The present invention has been made based on the technical background as described above and provides the following substrate treating solution.

### Means for Solving the Problems

The substrate treating solution according to the present invention comprises a polymer (A) and a solvent (B):
wherein
the solvent (B) comprises water (B-1);
the polymer (A) comprises an acidic polymer (A-1) having a pKa (H₂O) of −10 to 8 or a basic polymer (A-2) whose conjugate acid has a pKa (H₂O) of 6 to 14;
the content of the polymer (A) is 0.5 to 15 mass % based on the total mass of the substrate treating solution;
the content of the solvent (B) is 70 to 99.5 mass % based on the total mass of the substrate treating solution; and
the content of water (B-1) is 80 to 100 mass % based on the total mass of the solvent (B).

The method for manufacturing a substrate according to the present invention comprises the following steps:
(1) dripping the substrate treating solution according to the present invention on a substrate; and
(2) removing the substrate treating solution from the substrate.

The method for manufacturing a device according to the present invention comprises the above-mentioned method for manufacturing a substrate.

### Effects of the Invention

Using the substrate treating solution according to the present invention, it is possible to desire one or more of the following effects.

It is possible to efficiently remove debris; debris removal ratio is high; it is possible to efficiently remove debris containing metal; reattachment of debris is suppressed; removal of the substrate treating solution is easy; it is possible to remove debris from the substrate surface without using a liquid having high reactivity; it is possible to clean the substrate surface without using a high-risk liquid; it is suppressed that the substrate treating solution chemically damages the substrate surface; it is possible to remove debris from the substrate surface without intentionally charging the substrate; it is possible to etch the substrate surface; it is possible to flatten the substrate surface during etching.

### BRIEF DESCRIPTION OF THE DRAWINGS

FIG. 1 is a cross-sectional view schematically illustrating a state of the substrate surface in cleaning of the substrate according to the present invention.

### DETAILED DESCRIPTION OF THE INVENTION

### Mode for Carrying Out the Invention

### [Definition]

Unless otherwise specified in the present specification, the definitions and examples described in this paragraph are followed.

The singular form includes the plural form and “one” or “that” means “at least one”. An element of a concept can be expressed by a plurality of species, and when the amount (for example, mass % or mol %) is described, it means sum of the plurality of species.

“And/or” includes a combination of all elements and also includes single use of the element.

When a numerical range is indicated using “to” or “-”, it includes both endpoints and units thereof are common. For example, 5 to 25 mol % means 5 mol % or more and 25 mol % or less.

The descriptions such as “C_{x-y}”, “Cₓ-C_{y}” and “Cₓ” mean the number of carbons in a molecule or substituent. For example, C₁₋₆ alkyl means an alkyl chain having 1 or more and 6 or less carbons (methyl, ethyl, propyl, butyl, pentyl, hexyl etc.).

When a polymer has a plural types of repeating units, these repeating units copolymerize. These copolymerization may be any of alternating copolymerization, random copolymerization, block copolymerization, graft copolymerization, or a mixture thereof. When a polymer or resin is represented by a structural formula, n, m or the like that is attached next to parentheses indicate the number of repetitions.

Celsius is used as the temperature unit. For example, 20 degrees means 20 degrees Celsius.

The additive refers to a compound itself having a function thereof (for example, in the case of a base generator, a compound itself that generates a base). An embodiment in which the compound is dissolved or dispersed in a solvent and added to a composition is also possible. As one embodiment of the present invention, it is preferable that such a solvent is contained in the composition according to the present invention as the solvent (B) or another component.

Hereinafter, embodiments of the present invention are described in detail.

### [Substrate Treating Solution]

The substrate treating solution according to the present invention comprises a polymer (A) and a solvent (B), wherein the solvent (B) comprises water (B-1); the polymer (A) comprises an acidic polymer (A-1) having a pKa (H₂O) of −10 to 8 or a basic polymer (A-2) whose conjugate acid has a pKa (H₂O) of 6 to 14; the content of the polymer (A) is 0.5 to 15 mass % based on the total mass of the substrate treating solution; the content of the solvent (B) is 70 to 99.5 mass % based on the total mass of the substrate treating solution; and the content of water (B-1) is 80 to 100 mass % based on the total mass of the solvent (B).

The substrate treating solution according to the present invention is used to treat the substrate surface. The substrate treating solution according to the present invention is preferably a substrate cleaning solution or an etchant; more preferably a substrate cleaning solution. The substrate treating solution according to the present invention is applied on a substrate and then removed, thereby making it possible to remove debris on the substrate. The substrate treating solution according to the present invention can highly exhibit effect when debris is debris that contains metal. The substrate treating solution according to the present invention is preferably a substrate treating solution for removing metal debris. The etchant according to the present invention can etch the substrate surface.

Examples of metal debris include aluminum, potassium, titanium, chromium, iron, nickel, copper, calcium, manganese, cobalt, zinc, hafnium and tantalum.

### Polymer (A)

The substrate treating solution according to the present invention comprises a polymer (A).

The polymer (A) comprises an acidic polymer (A-1) having a pKa (H₂O) of −10 to 8 (preferably −8 to 7; more preferably −3 to 6; further more preferably −2 to 5) (hereinafter sometimes referred to as the acidic polymer) or a basic polymer (A-2) whose conjugate acid has a pKa (H₂O) of 6 to 14 (preferably 7 to 12; more preferably 7 to 11; even more preferably 8 to 10) (hereinafter sometimes referred to as the basic polymer). In the present specification, the basicity of the basic polymer (A-2) is indicated by pKa of its conjugate acid.

In the present invention, for the acid dissociation constant pKa (H₂O) or the acid dissociation constant pKa (H₂O) of the conjugate acid, structure retrieval thereof can be performed, for example, by Scifinder (trademark) to obtain the corresponding paper and to refer to the values described therein. Although not to be bound by theory, the polymer (A) having high solubility in water (B-1) is preferable because a residue is unlikely to be generated at the time of removal.

The polymer (A) comprises either an acidic polymer (A-1) or a basic polymer (A-2), and does not comprise both.

As the acidic polymer (A-1) or the basic polymer (A-2), a suitable one can be selected depending on debris attaching to the substrate. Although not to be bound by theory, the present inventors considered as follows. When debris (for example, debris that contains metal) is charged, even if cleaning is tried simply with water, debris and the substrate are electrically attracted to each other, so that debris sometimes cannot be removed by the mechanical force of water flow. It is assumed that when the substrate treating solution of the present invention is used; the polymer (A) comes into contact with debris in a liquid state as the whole substrate treating solution; the polymer (A) and debris have attracted each other by the intramolecular force to neutralize debris surface to make the electrical attraction between debris and the substrate disappear; and it becomes easy to remove debris from the interface of the substrate. Although not to be bound by theory, it is assumed that because (A) is a polymer, presenting various valences becomes possible, which makes the removal of debris having a non-uniform surface state easier. Although not to be bound by the theory, it is assumed that because (A) is a polymer, preventing the reattachment of debris is also possible, which is a state, for example, that the polymer (A) attracted to debris contains debris. Although not to be bound by theory, it is assumed that when there are a lot of debris having a positive charge, the removal of debris from the substrate becomes more efficient because the polymer (A) is an acidic polymer (A-1). It is assumed that when there are many debris having a negative charge, the removal of debris from the substrate becomes more efficient because the polymer (A) is a basic polymer (A-2). In one preferred embodiment of the present invention, the polymer (A) comprises an acidic polymer (A-1). Although not to be bound by theory, it is assumed that even if an acidic polymer (A-1) is used for debris having a negative charge, neutralizing it using a non-ionized group in the polymer is possible. It is assumed the same as for the relationship between debris having a positive charge and a basic polymer (A-2).

Although not to be bound by theory, the present inventors considered as follows as another embodiment. It is assumed that the presence of the solvent (B) (including water (B-1)) between the polymer (A) makes it possible to decrease the voids in the polymer (A) and decrease the uneven distribution of its contact with the substrate surface. Although not to be bound by theory, it is assumed possible to decrease the influence of the substrate surface using the polymer (A) instead of a low molecular compound.

When the polymer (A) comprises an acidic polymer (A-1), the pH of the substrate treating solution is preferably 1 to 7; more preferably 2 to 7; further preferably 5 to 7.

When the polymer (A) comprises a basic polymer (A-2), the pH of the substrate treating solution is preferably 7 to 14; more preferably 7 to 12; further preferably 7 to 9.

It is preferable to measure the pH by degassing in order to avoid the influence of the dissolution of carbon dioxide in the air.

The acidic polymer (A-1) preferably comprises a repeating unit represented by the formula (a-1):

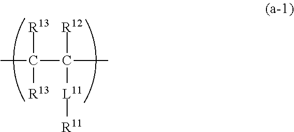

where
L¹¹ is a single bond, C₁₋₄ alkylene, phenylene, ether, carbonyl, amide or imide; preferably a single bond, methylene, ethylene, phenylene or amide; more preferably a single bond, phenylene or amide; further preferably a single bond or phenylene; further more preferably a single bond. When L¹¹ is amide or imide, H present in the amide or the imide may be replaced with methyl, but is preferably not replaced.

R¹¹ is carboxy, sulfo, phospho, C₁₋₄ alkyl or C₁₋₄ alkoxy; preferably carboxy, sulfo, isopropyl, t-butyl or methoxy; more preferably carboxy or sulfo; further preferably carboxy.

R¹² is H or methyl; preferably H.

R¹³ is each independently H, methyl or carboxy; preferably H or carboxy; more preferably H.

H in R¹², R¹³ and L¹¹, H contained in methyl and H contained in C₁₋₄ alkylene can be each independently replaced with F. The replacement with F may be a part of H (for example, —CH₃ to —CHF₂) or all (for example, —CH₃ to —CF₃); preferably all.

Preferable examples of the polymer comprising the repeating unit represented by the formula (a-1) include polyacrylic acid, polymaleic acid, polyvinyl sulfonic acid, polystyrene sulfonic acid, or any combination of any of these.

In the case of copolymerization, it is preferably random copolymerization, block copolymerization or alternating copolymerization; more preferably random copolymerization.

As one example, the following copolymer of maleic acid and acrylic acid is described. The copolymer is contained in (A-1) and has two types of repeating units represented by (a-1).

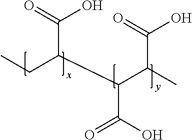

The acidic polymer (A-1) is more preferably selected from the group consisting of polyvinylsulfonic acid, poly(4-styrene sulfonic acid), polyacrylic acid, poly(N-isopropylacrylamide-co-methacrylic acid), poly(4-styrene sulfonic acid-co-maleic acid) and poly(methyl vinyl ether-alt-maleic acid).

The mass average molecular weight (Mw) of the acidic polymer (A-1) is preferably 500 to 500,000 (more preferably 1,000 to 100,000; further preferably 2,000 to 50,000; further more preferably 5,000 to 50,000; still further more preferably 5,000 to 40,000).

Here, in the present invention, Mw means a Mw in terms of polystyrene, which is measured by the gel permeation chromatography based on polystyrene. The same applies to the following.

The acidic polymer (A-1) can comprise a repeating unit other than the repeating unit represented by the formula (a-1), but the repeating unit other than the repeating unit represented by the formula (a-1) is preferably 50 mol % or less; more preferably 30 mol % or less; further preferably 5 mol % or less, based on the total repeating units constituting the polymer (A). It is also a preferred embodiment of the present invention that these are not contained (0%).

The basic polymer (A-2) preferably comprises a repeating unit represented by the formula (a-2-1) or a repeating unit represented by the formula (a-2-2).

The formula (a-2-1) is as follows.

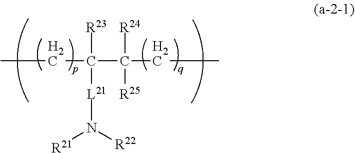

where
R²³, R²⁴ and R²⁵ are each independently H, C₁₋₄ alkyl or carboxy. R²³ and R²⁴ are preferably H. R²⁵ is preferably H or methyl; more preferably H.

L²¹ is a single bond or C₁₋₄ alkylene; preferably a single bond or methylene; more preferably a single bond. An embodiment in which L²¹ is methylene is also a preferred embodiment of the present invention.

R²¹ is a single bond, H or C₁₋₅ alkyl; preferably a single bond, H, methyl, ethyl, n-propyl or n-butyl; more preferably a single bond, H or methyl; further preferably a single bond or H; further more preferably H. When R²¹ is a single bond, it is bonded to R²⁵.

R²² is H, C₁₋₅ alkyl or C₁₋₅ acyl; preferably H, methyl, ethyl, n-propyl, n-butyl, acetyl or formyl; more preferably H, methyl, ethyl or n-propyl; further preferably H or n-propyl; further more preferably H.

Here, at least one of —CH₂— in the alkylene of L²¹, the alkyl of R²¹, and the alkyl or acyl of R²² can be each independently replaced with —NH—. Preferably, one of —CH₂— in the alkyl or acyl of R²² is replaced with —NH—. An embodiment in which the replacement with —NH— does not occur is also suitable.

The single bond or alkyl of R²¹, and the alkyl of R²⁵ can be bonded together to form a saturated or unsaturated heterocycle. Preferably, the single bond of R²¹ and the alkyl of R²⁵ are bonded to form a saturated heterocycle. An embodiment in which the heterocycle is not formed is also suitable.

The alkyl of R²¹, and the alkyl, acyl or formyl of R²² can be bonded together to form a saturated or unsaturated heterocycle. Preferably, the alkyl of R²¹ and the alkyl of R²² are bonded to form an unsaturated heterocycle. The above-mentioned replacement with the —NH— can be made for —CH₂— in R²¹ and/or R²² used for the above-mentioned bonding. An embodiment in which the heterocycle is not formed is also suitable.

p and q are each independently numbers of 0 to 1; preferably 0 or 1; more preferably 0.

The repeating unit of the polymer E: polyallylamine described later is concretely described by the formula (a-2-1). p=q=0. R²¹, R²², R²³, R²⁴ and R²⁵ are H. L²¹ is methylene.

The repeating unit of the following vinylpyrrolidone-vinylimidazole copolymer is concretely described by the formula (a-2-1). It has two types of repeating units, each of which is represented by the formula (a-2-1).

The part corresponding to vinylpyrrolidone is concretely described. p=q=0. R²³, R²⁴ and R²⁵ are H. L²¹ is a single bond. R²¹ is C₂ alkyl (ethyl). R²² is C₂ acyl (CH₃—CO—, acetyl). The alkyl of R²¹ and the acyl of R²² are bonded to form a saturated heterocycle (2-pyrrolidone).

The part corresponding to vinyl imidazole is concretely described. p=q=0. R²³, R²⁴ and R²⁵ are H. L²¹ is a single bond. R²¹ is C₁ alkyl (methyl). R²² is C₃ alkyl (n-propyl), and one of —CH₂— is replaced with —NH—. Further, the alkyl of R²¹ and the alkyl of R²² are bonded to form an unsaturated heterocycle (imidazole).

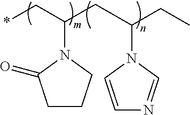

The repeating unit of the following polydiallylamine is concretely described by the formula (a-2-1). p=q=1. R²², R²³ and R²⁴ are H. L²¹ is methylene and R²⁵ is methyl. R²¹ is a single bond and bonded to R²⁵ to form a saturated heterocycle.

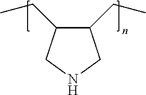

The following repeating unit is concretely described by the formula (a-2-1). p=q=0. R²³, R²⁴ and R²⁵ are H. L²¹ is a single bond. R²¹ is C₄ alkyl (n-butyl). R²² is C₂ acyl (CH₃—CO—, acetyl). The alkyl of R²¹ and the acyl of R²² are bonded to form a saturated heterocycle.

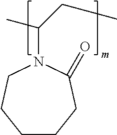

The formula (a-2-2) is as follows.

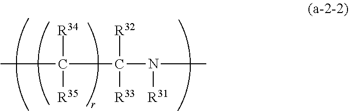

where
R³¹ is each independently H, a single bond, C₁₋₄ alkyl or carboxy (—COOH); preferably H, a single bond or methyl; more preferably H or a single bond; further preferably H. The single bond of R³¹ can be bonded to another repeating unit, and the single bond not used at the end of the polymer can be bonded to H or the like.

R³², R³³, R³⁴ and R³⁵ are each independently H, C₁₋₄ alkyl or carboxy; preferably H or methyl; more preferably H.

r is a number of 0 to 3; preferably 0 or 1; more preferably 1.

Examples of the polymer having a repeating unit represented by the formula (a-2-2) include polyethyleneimine. Polyethyleneimine may be linear or branched.

The linear polyethyleneimine is concretely described by the formula (a-2-2). r=1, and R³¹, R³², R³³, R³⁴ and R³⁵ are H.

The branched polyethyleneimine is concretely described by the formula (a-2-2). r=1, and R³¹ is H or a single bond. R³², R³³, R³⁴ and R³⁵ are H.

The polymer (A-2) is preferably selected from the group consisting of polyallylamine, polyvinylamine, polydiallylamine, and polyethyleneimine.

The Mw of the basic polymer (A-2) is preferably 500 to 500,000 (more preferably 1,000 to 200,000; further preferably 2,000 to 100,000; further more preferably 3,000 to 75,000).

The basic polymer (A-2) can comprise repeating units other than the repeating units represented by the formulae (a-2-1) and (a-2-2), but the repeating units other than the repeating units represented by the formulae (a-2-1) and (a-2-2) are preferably 50 mol % or less; more preferably 30 mol % or less; further preferably 5 mol % or less, based on the total repeating units constituting the polymer (A). It is also a preferred embodiment of the present invention that these are not contained (0%).

The polymer (A) can further comprise a polymer (A-3), which is different from the acidic polymer (A-1) and the basic polymer (A-2). Although not to be bound by theory, a polymer having good film forming properties can be used as the polymer (A-3). The polymer (A-3) is preferably not represented by any of the formulae (a-1), (a-2-1) and (a-2-2). The polymer (A-3) preferably has a pKa (H₂O) of 6 to 8. Examples of the polymer (A-3) include polyethylene oxide, polyvinyl alcohol, polyvinyl alcohol-polyethylene glycol graft copolymer, vinyl alcohol-vinyl acetate copolymer, polymethylvinyl ether, polyacrylamide, polyisopropylacrylamide, polyvinylpyrrolidone, polyvinylpyrrolidone-vinyl acetate copolymer, polyethylene oxide-polypropylene oxide block copolymer, methyl cellulose, ethyl cellulose, hydroxyethyl cellulose, hydroxypropyl cellulose and hydroxypropyl methyl cellulose.

The content of the polymer (A-3) is preferably 0 to 50 mass %; more preferably 1 to 20 mass %; further preferably 5 to 10 mass %, based on the total mass of the polymer (A). It is also a preferred embodiment of the present invention that the polymer (A-3) is not contained (0%).

The content of the polymer (A) is 0.5 to 15 mass % (preferably 0.8 to 10 mass %; more preferably 1.0 to 8 mass %) based on the total mass of the substrate treating solution.

### Solvent (B)

The substrate treating solution according to the present invention comprises a solvent (B). The solvent (B) comprises water (B-1).

The content of water (B-1) is 80 to 100 mass % (more preferably 90 to 100 mass %; further preferably 95 to 100 mass %; further more preferably 98 to 100 mass %) based on the total mass of the solvent (B). It is also a preferred embodiment that the solvent (B) does not contain any solvent other than water (B-1) (100 mass %).

The solvent (B) can further comprise an organic solvent (B-2).

Preferably, the organic solvent (B-2) has volatility. In the present invention, having volatility means that volatility is higher compared with water. For example, the boiling point of the solvent (B-2) at 1 atm is preferably 50 to 250° C.; more preferably 50 to 200° C.; further preferably 60 to 170° C.; further more preferably 70 to 150° C.

Examples of the organic solvent (B-2) include alcohols such as isopropanol (IPA); ethylene glycol monoalkyl ethers such as ethylene glycol monomethyl ether and ethylene glycol monoethyl ether; propylene glycol monoalkyl ethers such as propylene glycol monomethyl ether (PGME) and propylene glycol monoethyl ether (PGEE); lactic acid esters such as methyl lactate, ethyl lactate (EL) and butyl lactate (BL); ketones such as acetone and cyclopentanone; amides such as N,N-dimethylacetamide and N-methylpyrrolidone; lactones such as α-acetyl-γ-butyrolactone and γ-butyrolactone. These organic solvents can be used alone or in any combination of any two or more of these. The organic solvent (B-2) is more preferably an organic solvent having high water solubility.

The content of the solvent (B) is 70 to 99.5 mass % (preferably 80 to 99.5 mass %; more preferably 90 to 99.0 mass %; further preferably 95 to 99.0 mass %) based on the total mass of the substrate treating solution.

In another embodiment of the present invention, the solvent (B) further comprises a highly polar solvent (B-3). The highly polar solvent (B-3) is preferably a solvent having high boiling point and high polarity (B-3-1) or an ionic liquid (B-3-2). The highly polar solvent (B-3) is not water (B-1). Preferably, when the solvent (B) contains the highly polar solvent (B-3), it does not contain the organic solvent (B-2). In the present specification, the solvent having a dielectric constant of 10 or more at 25° C. is taken as the highly polar solvent (B-3). The upper limit of the dielectric constant of the highly polar solvent (B-3) is preferably 200; more preferably 100.

In one embodiment of the present invention, the highly polar solvent (B-3) is the solvent having high boiling point and high polarity (B-3-1). The solvent having high boiling point and high polarity (B-3-1) is a highly polar solvent and one having a standard boiling point of 150° C. or higher (preferably 160° C. or higher; more preferably 180° C. or higher).

Exemplified embodiments of the solvent having high boiling point and high polarity (B-3-1) include lactic acid esters such as n-butyl lactate (185° C.); lactones such as β-propiolactone (162° C.), γ-butyrolactone (204° C.), γ-valerolactone (207° C.) and γ-undecalactone (286° C.); monoalcohols such as benzyl alcohol (205° C.); polyhydric alcohols such as ethylene glycol (197° C.), 1,2-propylene glycol (188° C.), 1,3-butylene glycol (208° C.), triethylene glycol (165° C.), dipropylene glycol (230° C.) and glycerin (290° C.); polyhydric alcohol partial ethers such as ethylene glycol monobutyl ether (171° C.), ethylene glycol monophenyl ether (244° C.), diethylene glycol monomethyl ether (194° C.), diethylene glycol monoethyl ether (202° C.), triethylene glycol monomethyl ether (249° C.), diethylene glycol monoisopropyl ether (207° C.), diethylene glycol monobutyl ether (231° C.), triethylene glycol monobutyl ether (271° C.), diethylene glycol monophenyl ether (283° C.), ethylene glycol monobenzyl ether (256° C.), diethylene glycol monobenzyl ether (302° C.), dipropylene glycol monomethyl ether (187° C.) and tripropylene glycol monomethyl ether (242° C.); carbonates such as ethylene carbonate (244° C.), propylene carbonate (242° C.), butylene carbonate (251° C.) and glycerol 1,2-carbonate (200° C., 10 mmHg); furfural (162° C.), dimethylsulfoxide (189° C.), sulfolane (287° C.), succinonitrile (265° C.), nitrobenzene (211° C.); or any combination of any of these.

In a preferred embodiment of the present invention, the solvent having high boiling point and high polarity (B-3-1) is preferably γ-butyrolactone, γ-valerolactone, benzyl alcohol, ethylene glycol, 1,2-propylene glycol, glycerin, ethylene glycol monophenyl ether, diethylene glycol monomethyl ether, diethylene glycol monoethyl ether, ethylene glycol monobenzyl ether, ethylene carbonate, propylene carbonate, butylene carbonate, dimethylsulfoxide, or mixtures thereof; more preferably γ-butyrolactone, γ-valerolactone, glycerin, ethylene carbonate, propylene carbonate or dimethylsulfoxide.

In one embodiment of the present invention, the highly polar solvent (B-3) is an ionic liquid (B-3-2). The ionic liquid is a salt that exists as a liquid in a wide temperature range, and is a liquid consisting only of ions. Generally, a salt having a melting point of 100° C. or lower is defined as an ionic liquid. The ionic liquid (B-3-2) in the present invention has a melting point of 100° C. or lower (preferably 80° C. or lower; more preferably 60° C. or lower; further preferably 30° C. or lower).

Exemplified embodiments of the ionic liquid (B-3-2) include ammonium-based ionic liquids such as trimethylpropylammonium bis(trifluoromethanesulfonyl) imide,
2-hydroxyethyl-trimethylammonium L-(+)-lactate), methyltrioctylammonium bis(trifluoromethanesulfonyl) imide, methyltrioctylammonium thiosalicylate, tetradodecylammonium chloride,
tributylmethylammonium dibutylphosphate and tributylmethylammonium methylcarbonate;
imidazolium-based ionic liquids such as
1-allyl-3-methylimidazolium bromide,
1-allyl-3-methylimidazolium iodide,
1-benzyl-3-methylimidazolium tetrafluoroborate,
1,3-bis(cyanomethyl) imidazolium bis(trifluoromethylsulfonyl) imide and
1,3-bis(cyanomethyl) imidazolium chloride;
pyridinium-based ionic liquids such as 1-butylpyridinium bromide, 1-(3-cyanopropyl) pyridinium chloride,
1-ethylpyridinium tetrafluoroborate,
1-butyl-4-methylpyridinium tetrafluoroborate,
1-butyl-3-methylpyridinium bis(trifluoromethylsulfonyl) imide and 1-butyl-4-methylpyridinium iodide;
pyrrolidinium-based ionic liquids such as
1-butyl-1-methylpyrrolidinium bromide,
1-ethyl-1-methylpyrrolidinium tetrafluoroborate,
1-ethyl-1-methylpyrrolidinium bis(trifluoromethylsulfonyl) imide,
1-ethyl-1-methylpyrrolidinium bromide and
1-ethyl-1-methylpyrrolidinium hexafluorophosphate; or any mixture of any of these.

In one preferred embodiment of the present invention, the ionic liquid (B-3-2) is preferably ammonium-based ionic liquids, imidazolium-based ionic liquids, pyridinium-based ionic liquids, pyrrolidinium-based ionic liquids, or any mixture of any of these; more preferably ammonium-based ionic liquids or pyrrolidinium-based ionic liquids; further preferably
tetraethylammonium trifluoromethanesulfonate,
tetrapropylammonium trifluoromethanesulfonate,
propyltrimethylammonium trifluoromethanesulfonate,
butyltrimethylammonium trifluoromethanesulfonate,
benzyltrimethylammonium trifluoromethanesulfonate,
2-hydroxyethyltrimethylammonium trifluoromethanesulfonate,
diethylmethylmethoxyethylammonium trifluoromethanesulfonate,
1-methyl-1-propylpyrrolidinium trifluoromethanesulfonate,
1-(2-methoxyethyl)-1-methylpyrrolidinium trifluoromethanesulfonate, tetramethylammonium bis(trifluoromethanesulfonyl) imide,
tetraethylammonium bis(trifluoromethanesulfonyl) imide, tetrapropylammonium bis(trifluoromethanesulfonyl) imide,
propyltrimethylammonium bis(trifluoromethanesulfonyl) imide,
butyltrimethylammonium bis(trifluoromethanesulfonyl) imide,
benzyltrimethylammonium bis(trifluoromethanesulfonyl) imide,
2-hydroxyethyltrimethylammonium (trifluoromethanesulfonyl) imide,
1-methyl-1-propylpyrrolidinium bis(trifluoromethanesulfonyl) imide, or
diethylmethylmethoxyethylammonium (trifluoromethanesulfonyl) imide.

The content of the highly polar solvent (B-3) is 0.0 to 5 mass % (preferably 0.01 to 2 mass %; more preferably 0.05 to 1 mass %; further preferably 0.1 to 0.5 mass %) based on the total mass of the substrate treating solution. It is also a preferred embodiment of the present invention that the highly polar solvent (B-3) is not contained (0.00 mass %).

Although not to be bound by theory, it is assumed that by containing the highly polar solvent (B-3) in the substrate treating solution, the liquid phase is prevented from being excessively decreased in the process, and the environment and time for debris to interact with the polymer (A) can be increased.

The substrate treating solution according to the present invention can further comprise an acid (C) or a base (D).

When the treating solution according to the present invention comprises an acidic polymer (A-1), it preferably further comprises a base (D), and when it comprises a basic polymer (A-2), it preferably further comprises an acid (C). Although not to be bound by theory, it is assumed that these combinations can prevent debris removed from the substrate from reattaching, and the removal of debris can be more efficiently performed. Although not to be bound by theory, it is assumed that these combinations are hydrated in the state of the treating solution, but the amount of the solvent decreases after being dripped on the substrate, so that a part of the acid (C) or the base (D) are produced as a salt. Although not to be bound by theory, it is assumed that these combinations make it possible to bring the pH of the substrate treating solution as a whole closer to neutral. Although not to be bound by theory, it is assumed that since the acid (C) or base (D) is decreased from the liquid and salt (for example, by vaporization) prior to the polymer (A) in a step such as spin-drying, an environment in which the interaction between the polymer (A) and debris is easier is formed.

### Acid (C)

The acid (C) is preferably selected from the group consisting of hydrogen halides, nitric acid, sulfuric acid, phosphoric acid, carboxylic acids, sulfonic acids, imides and salts thereof, and any combination of any of these; more preferably selected from the group consisting of hydrochloric acid, hydrobromic acid, nitric acid, sulfuric acid, phosphoric acid, acetic acid, oxalic acid, glycolic acid, citric acid, ammonium tartrate, trifluoroacetic acid, methanesulfonic acid, ethanesulfonic acid, trifluoromethanesulfonic acid, sulfonylimide and any combination of any of these.

The molecular weight of the acid (C) is preferably 15 to 300 (more preferably 30 to 250; further preferably 50 to 200; further more preferably 60 to 184).

The content of the acid (C) is preferably 0.01 to 5 mass % (more preferably 0.1 to 4 mass %; further preferably 0.5 to 2 mass %) based on the total mass of the substrate treating solution.

### Base (D)

The base (D) is preferably selected from the group consisting of ammonia, primary amines, secondary amines, tertiary amines, quaternary ammonium salts, and any combination of any of these; more preferably selected from the group consisting of ammonia, diethylamine, triethylamine, ethylenediamine, diethylethanolamine, isobutylamine, diisobutylamine, tetramethylammonium hydroxide, tetraethylammonium hydroxide, tetrapropylammonium hydroxide, tetrabutylammonium hydroxide, and any combination of any of these.

The molecular weight of the base (D) is preferably 15 to 300 (more preferably 30 to 300; further preferably 50 to 280; further more preferably 70 to 260).

The content of the base (D) is preferably 0.01 to 5 mass % (more preferably 0.1 to 4 mass %; further preferably 0.5 to 2 mass %) based on the total mass of the substrate treating solution.

### Surfactant (E)

The substrate treating solution according to the present invention can further comprise a surfactant (E). The surfactant (E) is useful for improving coatability and solubility. Examples of the surfactant that can be used in the present invention include (I) anionic surfactant, (II) cationic surfactant, or (III) nonionic surfactant, and more particularly, (I) alkyl sulfonate, alkyl benzene sulfonic acid and alkyl benzene sulfonate, (II) lauryl pyridinium chloride and lauryl methyl ammonium chloride, and (III) polyoxyethylene octyl ether, polyoxyethylene lauryl ether, polyoxyethylene acetylenic glycol ether, fluorine-containing surfactants (for example, Fluorad (3M), MEGAFACE (DIC), Surflon (AGC Seimi Chemical) and organic siloxane surfactants (for example, KF-53, KP341 (Shinetsu Chemical Industry)).

These surfactants can be used alone or in combination of two or more of these.

The content of the surfactant (E) is preferably 0.01 to 5 mass % (more preferably 0.02 to 4 mass %; further preferably 0.05 to 2 mass %) based on the total mass of the substrate treating solution. It is also one embodiment of the present invention that any surfactant (E) is not contained (0 mass %).

Further additive (F)

The substrate treating solution according to the present invention can further comprise a further additive (F) other than the above-mentioned components (A) to (E). The further additive (F) preferably comprises an antibacterial agent, a bactericide, a preservative or an antifungal agent.

The content of the further additive (F) is preferably 0.01 to 10 mass % (more preferably 0.02 to 5 mass %; further preferably 0.05 to 2 mass %) based on the total mass of the substrate treating solution. It is also a preferred embodiment of the present invention that the substrate treating solution according to the present invention does not contain the further additive (F) (0 mass %).

### [Method for Manufacturing a Substrate]

The method for manufacturing a substrate according to the present invention comprises the following steps:
(1) dripping the substrate treating solution according to the present invention on a substrate; and
(2) removing the substrate treating solution from the substrate.

The numbers in parentheses indicate the order of the steps. For example, when the steps (0-1), (0-2), and (1) are described, the order of the steps is as described above.

The substrate to be cleaned in the present invention include semiconductor wafers, glass substrates for liquid crystal display, glass substrates for organic EL display, glass substrates for plasma display, substrates for optical disk, substrates for magnetic disk, substrates for magneto-optical disk, glass substrates for photomask, substrates for solar cell, and the like. The substrate may be a non-processed substrate (for example, a bare wafer) or a processed substrate (for example, a patterned substrate). The substrate may be composed by laminating a plurality of layers. Preferably, the substrate surface is a semiconductor. The semiconductor may be composed of oxide, nitride, metal, and any combination of any of these.

It is also a preferred embodiment of the present invention that the substrate treating solution according to the present invention is an etchant. When the substrate treating solution is an etchant, the metal on the substrate surface is oxidized. The oxidation may be made for all or part of the substrate surface. The oxidation may be either intentionally made or environmentally induced. Although there is no intention to limit the present invention, examples of the metal to be oxidized on the substrate surface include Cu, Al, Ti, W, Ni, Cr, In, Sn, Zn, Ga or any combination of any of these; preferably Cu, Al, Ti or any combination of any of these; more preferably Cu. Although there is no intention to limit the present invention, suitable metal oxide includes CuO, TiN, In₂O₃, SnO₂. Although not to be bound by theory, it is assumed that the presence of the solvent (B) (containing water (B-1)) between the polymer (A) makes it possible to decrease the voids in the polymer (A) and to decrease uneven distribution of contact with the metal oxide surface. Although not to be bound by theory, it is assumed possible to decrease the influence of the metal oxide surface (for example, variation in the bonding state) and etch the oxide film flat, using the polymer (A) instead of the low molecular compound.

### Step (1)

In the step (1), the treating solution according to the present invention is dripped on a substrate. It is preferable that the dripping of the treating solution is performed by dripping the substrate treating solution nearly at the center of the horizontally postured substrate through a nozzle or the like in an apparatus suitable for substrate cleaning. The dripping may be in the form of liquid column or dropping. At the time of the dripping, the substrate is rotated, for example, at 10 to several tens of rpm, so that the generation of dripping traces can be suppressed.

The dripping amount is preferably 0.5 to 10 cc. These conditions can be adjusted so that the substrate treating solution is uniformly applied and spread.

After dripping, a part of the solvent (B) can be removed to dry the coating solution. The removal of this solvent can be performed by spin-drying, raising the temperature in the apparatus, heating with a hot plate, or the like, and is preferably performed by spin-drying. Spin-drying is preferably conducted at 500 to 3,000 rpm (more preferably 1,000 to 2,000 rpm) and preferably for 0.5 to 90 seconds (more preferably 5 to 80 seconds; further preferably 15 to 70 seconds). As a result, the solvent (B) can be dried while spreading the substrate treating solution over the entire surface of the substrate. Preferably, the substrate is a disk-shaped substrate having a diameter of 200 to 600 mm (more preferably 200 to 400 mm).

After spin-drying, a step of heating with a hot plate in the air, for example, at 40 to 150° C. (preferably 50 to 100° C.) can also be contained. Heating is conducted for preferably 30 to 180 seconds; more preferably 45 to 120 seconds.

### Step (2)

In the step (2), the substrate treating solution dripped on the substrate is removed. The removal method is not particularly limited, but in a preferred embodiment, it can be performed by supplying a rinse on the substrate. The rinse can be supplied by dripping, spraying, or immersion. The dripping may be performed so as to form a liquid pool (paddle) on the substrate, or may be performed by continuously dripping. In one embodiment of the present invention, the rinse is dripped at the center of the substrate while the substrate is rotated at 500 to 800 rpm. More preferably, the removal is performed by continuously dripping a rinse on the substrate to replace the substrate treating solution with it. After that, the rinse is removed to turn into a state that debris is removed from the substrate and the substrate is cleaned. Removal of the rinse is preferably performed by spin-drying.

The rinse preferably comprises water. The content of water contained in the rinse is preferably 70 to 100 mass %; more preferably 80 to 100 mass %; further preferably 90 to 100 mass %, based on the total mass of the rinse. It is also a preferred embodiment of the present invention that the rinse consists of water (100 mass %).

Although not to be bound by theory, it is assumed that due to the large commonality between the solvent (B) of the substrate treating solution and the liquid components of the rinse, the polymer (A) derived from the substrate treating solution is dissolved again, and the polymer (A) that attracts debris and debris can be removed.

Although there is no intention to limit the present invention and this is not to be bound by theory, in order to understand the present invention, one embodiment of the method for manufacturing a cleaned substrate using the substrate treating solution according to the present invention is described using a schematic drawing.

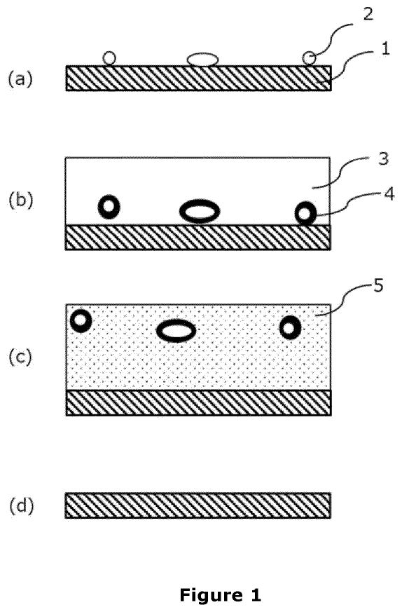

FIG. 1(a) shows a state in which debris 2 is attached to the substrate 1. FIG. 1(b) shows a state after the dripping of the substrate treating solution according to the present invention on this substrate. At this time, the polymer in the substrate treating solution is chemically adsorbed to debris, and debris adsorbed by the polymer 4 is formed. FIG. 1(c) shows a state in which from the state in which the substrate treating solution is present, a rinse 5 is applied and the substrate treating solution is replaced with the rinse. Debris is removed together with the rinse in a state of adsorbed by the polymer. The state of the substrate obtained by the cleaning is shown by FIG. 1(d).

The method for manufacturing a substrate according to the present invention preferably further comprises at least one of the following steps:
(0-1) processing a pattern on the substrate by etching, and removing the etching mask;
(0-2) cleaning the substrate;
(0-3) prewetting the substrate; and
(0-4) cleaning the substrate.

### Step (0-1)

In the step (0-1), a pattern is processed on the substrate by etching, and the etching mask is removed. The substrate to be cleaned may be a processed substrate, and the processing may be performed by a lithography technique.

### Step (0-2)

In the step (0-2), the substrate is cleaned with a known cleaning solution (such as rinse) in order to decrease the number of particles on the substrate. It is one of the objects of the present invention to remove a few particles remaining by this.

### Step (0-3)

In the step (0-3), the substrate is subjected to prewetting. It is also a preferred embodiment to contain this step in order to improve the coatability of the substrate treating solution of the present invention and spread it uniformly on the substrate. The preferable liquid used for prewetting (prewetting liquid) includes IPA, PGME, PGMEA, PGEE, n-butanol (nBA), pure water, and any combination of any of these.

In order to increase the reactivity of debris with the substrate treating solution according to the present invention, prewetting with hydrogen peroxide solution is also a preferred embodiment of the present invention. When prewetting with hydrogen peroxide solution is performed, it is preferable that the applied hydrogen peroxide solution is removed by spin-drying, and it is preferable that the step (0-4) described later is not performed. The same effect may be obtained by compounding hydrogen peroxide to the substrate treating solution.

### Step (0-4)

In order to replace the prewetting liquid in the step (0-3), a step of cleaning the substrate is also a preferred embodiment. It is also one embodiment of the present invention that inserting the step (0-2) makes the step (0-4) not required.

### [Device]

A device can be manufactured by further processing the substrate manufactured by the cleaning method according to the present invention. Known methods can be used for the processing. The processed substrate can be, if desired, cut into chips, connected to a lead frame, and packaged with resin. Examples of the device include a semiconductor, a liquid crystal display device, an organic EL display device, a plasma display device and a solar cell device.

The present invention is described below with reference to various examples. The embodiment of the present invention is not limited only to these examples.

### Preparation of Polymer A Aqueous Solution

100 g of “poly(vinyl sulfonic acid, sodium salt) solution” (Sigma-Aldrich) is passed through a column tube filled with 200 mL of ion exchange resin ESP-2 (Organo) to remove metal, and then this is diluted with DIW (distilled ion exchange water) to prepare a 6 mass % polymer A aqueous solution.

The polymer A has a pKa (H₂O) of −2 and a Mw of 20,000.

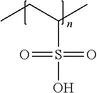

### Preparation of Polymer B Aqueous Solution

A “poly (4-styrene sulfonic acid) solution (Sigma-Aldrich)” is treated in the same manner as in the preparation of the polymer A to prepare a 6 mass % polymer B aqueous solution.

The polymer B has a pKa (H₂O) of 2 and a Mw of 75,000.

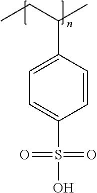

### Preparation of Polymer C Aqueous Solution

A “poly (acrylic acid, sodium salt) solution” (Sigma-Aldrich) is treated in the same manner as in the preparation of the polymer A to prepare a 6 mass % polymer C aqueous solution.

The polymer C has a pKa (H₂O) of 5 and a Mw of 8,000.

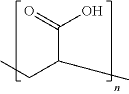

### Preparation of Polymer D Aqueous Solution

A “poly (acrylic acid-co-maleic acid) solution” (Sigma-Aldrich) is treated in the same manner as in the preparation of the polymer A to prepare a 6 mass % polymer D aqueous solution.

The polymer D has a pKa (H₂O) of 3 and a Mw of 3,000.

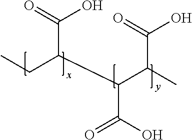

### Preparation of Polymer E Aqueous Solution

A “poly (allylamine) solution” (Sigma-Aldrich) is treated in the same manner as in the preparation of the polymer A to prepare a 6 mass % polymer E aqueous solution.

The pKa (H₂O) of the conjugate acid of the polymer E is 10, and the polymer E has a Mw of 65,000.

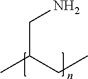

### Preparation of Polymer F Aqueous Solution

80 g of ion-exchanged water is mixed with 20 g of “polyethyleneimine, branched (Sigma-Aldrich)” and the mixture is stirred to obtain a 20 mass % polyethyleneimine aqueous solution. This aqueous solution is passed through a column tube in the same manner as in the preparation of the polymer A to remove metal such as sodium. This is diluted with DIW to prepare a 6 mass % polymer F aqueous solution.

The pKa (H₂O) of the conjugate acid of the polymer F is 9, and the polymer F has a Mw of 25,000.

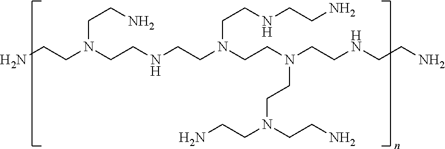

### Preparation of Example Treating Solution 1

The 6 mass % polymer A aqueous solution and a surfactant “Pionin A-40” (alkylbenzene sulfonic acid, Takemoto Oil & Fat) are added to DIW. Water is added to the mixture so that the solid components thereof have the mass ratio shown in Table 1 and the solid components are adjusted to have a total mass ratio of 4 mass %. (Here, the solid component means a component other than water contained in the treating solution. For example, in the 6 mass % polymer A aqueous solution, the components other than water correspond to the solid components in the polymer A aqueous solution. In the case of a substance that is liquid at normal temperature and pressure, the mass ratio is calculated taking it as a solid component in this calculation.)

In this treating solution, the mass ratio of the polymer A:Pionin A-40 is 97:3. This liquid is mixed using a stirrer at room temperature for 60 minutes. It is visually confirmed that the solute is completely dissolved. This liquid is filtered through a hydrophilic fluororesin filter having a pore size of 0.2 μm. As a result, Example Treating Solution 1 is obtained. The pH of Example Treating Solution 1 is 1.

### Preparation of Example Treating Solutions 2 to 10 and Comparative Example Treating Solutions 1 and 2

Example Treating Solutions 2 to 10 and Comparative Example Treating Solutions 1 and 2 are Example Treating Solution 1 except that each component and each ratio are changed as described in Table 1. The pH of the obtained treating solution is shown in Table 1.

TABLE 1

| | | | | Highly polar | | pH of |
|---|---|---|---|---|---|---|
| | Polymer | Acid | Base | solvent | Surfactant | Treating |
| | (A) | (C) | (D) | (B-3) | (E) | Solution |
| Example | A (97) | — | — | — | Pionin A-40 (3) | 1 |
| Treating | | | | | | |
| Solution 1 | | | | | | |
| Example | A (94) | | Ammonia (3) | — | Pionin A-40 (3) | 6 |
| Treating | | | | | | |
| Solution 2 | | | | | | |
| Example | B (94) | — | Ammonia (3) | — | Pionin A-40 (3) | 6 |
| Treating | | | | | | |
| Solution 3 | | | | | | |
| Example | C (97) | — | — | — | Pionin A-40 (3) | 3 |
| Treating | | | | | | |
| Solution 4 | | | | | | |
| Example | D (79) | — | Triethylamine (18) | — | Pionin A-40 (3) | 6 |
| Treating | | | | | | |
| Solution 5 | | | | | | |
| Example | E (97) | — | — | — | Pionin A-40 (3) | 11 |
| Treating | | | | | | |
| Solution 6 | | | | | | |
| Example | F (76) | Acetic acid (21) | — | — | Pionin A-40 (3) | 8 |
| Treating | | | | | | |
| Solution 7 | | | | | | |
| Example | A (92) | — | — | Trimethylpro- | Pionin A-40 (3) | 1 |
| Treating | | | | pylammonium | | |
| Solution 8 | | | | bis(trifluoro- | | |
| | | | | methanesulfonyl) | | |
| | | | | imide (5) | | |
| Example | A (92) | — | — | Glycerin (5) | Pionin A-40 (3) | 1 |
| Treating | | | | | | |
| Solution 9 | | | | | | |
| Example | A (92) | — | — | Dimethyl- | Pionin A-40 (3) | 1 |
| Treating | | | | sulfoxide (5) | | |
| Solution 10 | | | | | | |
| Comparative | — | — | — | — | Pionin A-40 (100) | 2 |
| Example | | | | | | |
| Treating | | | | | | |
| Solution 1 | | | | | | |
| Comparative | — | Concentrated | — | — | — | 1 |
| Example | | sulfuric acid (30), | | | | |
| Treating | | 30 mass % | | | | |
| Solution 2 | | Hydrogen | | | | |
| | | peroxide (70) | | | | |

In the table, the numerical values in parentheses in each component indicate the mass ratio. As trimethylpropylammonium bis(trifluoromethanesulfonyl) imide, the product manufactured by Tokyo Chemical Industry (hereinafter, TCI) is used.

### Formation of Metal-Contaminated Wafer

“Aluminum standard stock solution (Al 1000)”, “chromium standard stock solution (Cr 1000)”, “iron standard stock solution (Fe 1000)”, and “titanium standard stock solution (Ti 1000)” (Fujifilm Wako Pure Chemical) are prepared. The concentration of each metal is 0.1 mass %. These are added to DIW and adjusted so that each metal has 10⁺¹⁴ atom/cm³. This is mixed at room temperature for 60 minutes to prepare a metal-containing liquid in which aluminum, chromium, iron and titanium are mixed. The metal-containing liquid is applied on an 8-inch Si wafer and spin-dried. As a result, a metal-contaminated wafer contaminated with 10⁺¹² atom/cm² is obtained. The metal concentration on the wafer surface is confirmed by the VPD-TXRF method.

### Cleaning of Metal-Contaminated Wafer

Hydrogen peroxide solution (for the use of precision analysis, Fujifilm Wako Pure Chemical) is added to Example Treating Solution 1 so that the content thereof becomes 6 mass %, and the mixture is shaken for 1 minute. The obtained liquid is dripped onto the substrate. This is spin-dried at 800 rpm for 30 seconds. The spin-dried wafer is heated at 60° C. for 60 seconds and rinsed with DIW for 60 seconds. The metal concentration of the cleaned wafer is analyzed by the VPD-TXRF method. The results obtained are shown in Table 2.

The same evaluation is performed for Example Treating Solutions 2 to 10 and Comparative Example Treating Solutions 1 and 2. The results are shown in Table 2.

TABLE 2

| Removal ratio | Al | Cr | Fe | Ti |
|---|---|---|---|---|
| Example Treating Solution 1 | 82% | 55% | 81% | 71% |
| Example Treating Solution 2 | 83% | 54% | 83% | 70% |
| Example Treating Solution 3 | 85% | 57% | 80% | 69% |
| Example Treating Solution 4 | 81% | 56% | 90% | 81% |
| Example Treating Solution 5 | 84% | 61% | 91% | 82% |
| Example Treating Solution 6 | 71% | 61% | 82% | 73% |
| Example Treating Solution 7 | 72% | 60% | 81% | 74% |
| Example Treating Solution 8 | 91% | 72% | 84% | 81% |
| Example Treating Solution 9 | 93% | 68% | 87% | 83% |
| Example Treating Solution 10 | 92% | 75% | 82% | 82% |
| Comparative Example Treating Solution 1 | 48% | 42% | 76% | 35% |
| Comparative Example Treating Solution 2 | 65% | 35% | 79% | 60% |

### Formation of Metal Oxide Film Wafer

A Si wafer whose surface is covered with copper having a film thickness of 200 nm is prepared by PVD. This is heated at 180° C. for 1 minute to prepare a metal oxide film wafer having a copper oxide film of 30 nm on the copper surface.

### Etching of Metal Oxide Film

The above-mentioned metal oxide film wafer is prepared. Example Treating Solution 2 is dripped on this and spin-dried at 800 rpm for 30 seconds. This wafer is heated at 100° C. for 60 seconds. Rinsing is performed by pouring DIW on the wafer surface for 60 seconds. The above-mentioned steps, which are from dripping of the treating solution to rinsing, are further repeated four times.

### Evaluation of Etching Amount

An SEM section after etching the metal oxide film is formed, an SEM photograph is obtained with SU8220 (Hitachi High-Tech), and the thickness of the copper oxide film is measured. The thickness decreased by etching the metal oxide film is taken as the etching amount. The results obtained are shown in Table 4.

### Evaluation of Surface Roughness

The surface roughness of the wafer before and after etching is measured. The root mean square roughness is measured by AFM5300E (Hitachi High-Tech) and this is evaluated as the surface roughness. The results obtained are shown in Table 4.

### Preparation of Example Treating Solutions 11 to 13

Example Treating Solutions 11 to 13 are prepared in the same manner as in the preparation of Example Treating Solution 1 except that each component and each ratio are changed as shown in Table 3.

For these, the above-mentioned etching of the metal oxide film, evaluation of the etching amount and evaluation of the surface roughness are performed. The results are shown in Table 4.

TABLE 3

| | Polymer (A) | Acid (C) | Base (D) | Highly polar solvent (B-3) | Surfactant (E) |
|---|---|---|---|---|---|
| Example Treating | A (89) | — | Ammonia | Trimethylpropylammonium | Pionin A-40 (3) |
| Solution 11 | | | (3) | bis(trifluoromethanesulfonyl) | |
| | | | | imide (5) | |
| Example Treating | A (89) | — | Ammonia | Glycerin (5) | Pionin A-40 (3) |
| Solution 12 | | | (3) | | |
| Example Treating | A (89) | — | Ammonia | Dimethylsulfoxide (5) | Pionin A-40 (3) |
| Solution 13 | | | (3) | | |

TABLE 4

| | Etching | Surface |
|---|---|---|
| | amount | roughness |
| Before ethcing | — | 1.28 nm |
| Example Treating Solution 2 | 6 nm | 1.13 nm |
| Example Treating Solution 3 | 5 nm | 1.16 nm |
| Example Treating Solution 4 | 6 nm | 1.02 nm |
| Example Treating Solution 7 | 5 nm | 1.07 nm |
| Example Treating Solution 11 | 9 nm | 1.11 nm |
| Example Treating Solution 12 | 8 nm | 1.08 nm |
| Example Treating Solution 13 | 9 nm | 1.06 nm |
| Comparative Example Treating Solution 1 | 15 nm | 1.52 nm |

Although not to be bound by theory, it can be confirmed that when an example treating solution is used as an etchant, the metal oxide film can be etched and the surface roughness can be further decreased as compared with Comparative Example Treating Solution 1.

### EXPLANATION OF SYMBOLS

1. substrate
2. debris
3. substrate treating solution
4. debris adsorbed by polymer
5. rinse

1.-14. (canceled)

15. A substrate treating solution comprising a polymer (A) and a solvent (B):
wherein
the solvent (B) comprises water (B-1);
the polymer (A) comprises an acidic polymer (A-1) having a pKa (H₂O) of −10 to 8 or a basic polymer (A-2) whose conjugate acid has a pKa (H₂O) of 6 to 14;
the content of the polymer (A) is 0.5 to 15 mass % based on the total mass of the substrate treating solution;
the content of the solvent (B) is 70 to 99.5 mass % based on the total mass of the substrate treating solution; and
the content of water (B-1) is 80 to 100 mass % based on the total mass of the solvent (B).

16. The substrate treating solution according to claim 15, further comprising an acid (C) or a base (D):
wherein
the molecular weight of the acid (C) is 15 to 600; and
the molecular weight of the base (D) is 15 to 600.

17. The substrate treating solution according to claim 15, wherein
the acidic polymer (A-1) comprises a repeating unit represented by the formula (a-1); or
the basic polymer (A-2) comprises a repeating unit represented by the formula (a-2-1) or a repeating unit represented by the formula (a-2-2): 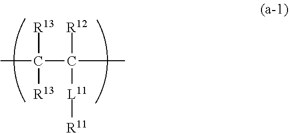
where
L¹¹ is a single bond, C₁₋₄ alkylene, phenylene, ether, carbonyl, amide or imide;
R¹¹ is carboxy, sulfo, phospho, C₁₋₄ alkyl or C₁₋₄ alkoxy;
R¹² is H or methyl; and
R¹³ is each independently H, methyl or carboxy;
where
H in R¹², R¹³ and L¹¹, and H contained in methyl and C₁₋₄ alkylene can be replaced with F, 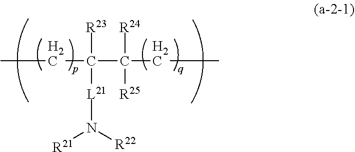
where
R²³, R²⁴ and R²⁵ are each independently H, C₁₋₄ alkyl or carboxy;
L²¹ is a single bond or C₁₋₄ alkylene;
R²¹ is a single bond, H or C₁₋₅ alkyl; and
R²² is H, C₁₋₅ alkyl or C₁₋₅ acyl;
where
at least one of —CH₂— in the alkylene of L²¹, the alkyl of R²¹, and the alkyl or acyl of R²² can be each independently replaced with —NH—;
the single bond or alkyl of R²¹, and the alkyl of R²⁵ can be bonded together to form a saturated or unsaturated heterocycle; and
the alkyl of R²¹, the alkyl, acyl or formyl of R²² can be bonded together to form a saturated or unsaturated heterocycle;
p and q are each independently numbers of 0 to 1, and 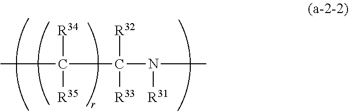
where
R³¹ is each independently H, a single bond, C₁₋₄ alkyl or carboxy;
R³², R³³, R³⁴ and R³⁵ are each independently H, C₁₋₄ alkyl or carboxy; and
r is a number of 0 to 3.

18. The substrate treating solution according to claim 16, wherein
the acid (C) is selected from the group consisting of hydrogen halides, nitric acid, sulfuric acid, phosphoric acid, carboxylic acids, sulfonic acids, imides and salts thereof, and any combination of any of these; or
the base (D) is selected from the group consisting of ammonia, primary amines, secondary amines, tertiary amines, quaternary ammonium salts, and any combination of any of these.

19. The substrate treating solution according to claim 15, wherein
the Mw (mass average molecular weight) of the acidic polymer (A-1) is 500 to 500,000; or
the Mw of the basic polymer (A-2) is 500 to 500,000.

20. The substrate treating solution according to claim 16, further comprising a surfactant (E).

21. The substrate treating solution according to claim 20, further comprising an additive (F).

22. The substrate treating solution according to claim 21, wherein the additive (F) comprises an antibacterial agent, a bactericide, a preservative or an antifungal agent.

23. The substrate treating solution according to claim 16, wherein
the content of the acid (C) is 0.01 to 5 mass % based on the total mass of the substrate treating solution; or
the content of the base (D) is 0.01 to 5 mass % based on the total mass of the substrate treating solution.

24. The substrate treating solution according to claim 21, wherein
the content of the acid (C) is 0.01 to 5 mass % based on the total mass of the substrate treating solution; or
the content of the base (D) is 0.01 to 5 mass % based on the total mass of the substrate treating solution:
the content of the surfactant (E) is 0.01 to 5 mass % based on the total mass of the substrate treating solution; or
the content of the further additive (F) is 0.01 to 10 mass % based on the total weight of the substrate treating solution.

25. The substrate treating solution according to claim 15, wherein
the acidic polymer (A-1) is selected from the group consisting of polyvinylsulfonic acid, poly(4-styrene sulfonic acid), polyacrylic acid, poly(N-isopropylacrylamide-co-methacrylic acid), poly(4-styrene sulfonic acid-co-maleic acid), copolymer of tetrafluoroethylene and perfluoro(3-oxa-4-pentensulfonic acid), copolymer of tetrafluoroethylene and perfluoro(3-oxa-4-pentenic acid), and poly(methyl vinyl ether-alt-maleic acid); or
the basic polymer (A-2) is selected from the group consisting of polyallylamine, polyvinylamine, polydiallylamine, and polyethyleneimine.

26. The substrate treating solution according to claim 16, wherein
the acid (C) is selected from the group consisting of hydrochloric acid, hydrobromic acid, nitric acid, sulfuric acid, phosphoric acid, acetic acid, oxalic acid, glycolic acid, citric acid, ammonium tartrate, methanesulfonic acid, ethanesulfonic acid, trifluoroacetic acid, trifluoromethanesulfonic acid, bis(nonafluorobutanesulfonyl) imide, and any combination of any of these; or the base (D) is selected from the group consisting of diethylamine, triethylamine, ethylenediamine, diethylethanolamine, isobutylamine, diisobutylamine, tetramethylammonium hydroxide, tetraethylammonium hydroxide, tetrapropylammonium hydroxide, tetrabutylammonium hydroxide, and any combination of any of these.

27. The substrate treating solution according to claim 15, which is a substrate treating solution for removing metal debris.

28. A method for manufacturing a substrate comprising the following steps:
(1) dripping the substrate treating solution according to claim 15 on a substrate; and
(2) removing the substrate treating solution from the substrate.

29. The method for manufacturing a substrate according to claim 28, further comprising at least one of the following steps:
(0-1) processing a pattern on the substrate by etching, and removing the etching mask;
(0-2) cleaning the substrate;
(0-3) prewetting the substrate; and
(0-4) cleaning the substrate.

30. The method for manufacturing a substrate according to claim 28, wherein the removal in the step (2) is performed by replacing a rinse with the substrate treating solution.

31. The method for manufacturing a substrate according to claim 28, wherein the removal in the step (2) is performed by replacing a rinse with the substrate treating solution:
wherein the rinse comprises water; and the content of water comprised in the rinse is 70 to 100 mass % based on the total mass of the rinse.

32. A method for manufacturing a device comprising the method for manufacturing a substrate according to claim 28.
